(19) United States
(12) Patent Application Publication
(10) Pub. No.: US 2017/0123320 A1
(43) Pub. Date: May 4, 2017

(54) METHOD FOR REMOVING PHOTORESIST

(71) Applicant: BOE TECHNOLOGY GROUP CO., LTD., Beijing (CN)

(72) Inventor: Hui TIAN, Beijing (CN)

(21) Appl. No.: 14/439,976

(22) PCT Filed: Oct. 16, 2014
(86) PCT No.: PCT/CN2014/088766

§ 371 Date: Apr. 30, 2015

(30) Foreign Application Priority Data
May 15, 2014 (CN) 201410206695.9

(51) Int. Cl. G03F 7/30; G03F 7/42

(52) U.S. Cl. CPC G03F 7/3092; G03F 7/42

(57) ABSTRACT

A method for removing photoresist comprising: depositing an oxide film on a base substrate on which photoresist has been formed; treating the oxide film by UV light; peeling off the oxide film; and removing the photoresist.

### TECHNICAL FIELD

Embodiments of the present disclosure relate to a method for removing photoresist.

### BACKGROUND

During manufacture of a display device and a semiconductor device, necessary film patterns are usually formed through patterning processes. Wherein the patterning processes comprise coating photoresist on a film; exposing and developing the photoresist through a mask, to form a photoresist removed portion and a photoresist remained portion after the development; etching the film uncovered by the photoresist to form required film patterns; and removing the remained photoresist.

Conventionally, the commonly used method for removing photoresist is ashing and fully wet cleaning method. Ashing is a method in which the photoresist is removed through reacting active ions with the photoresist in a plasma atmosphere and bombarding the photoresist with oxygen plasmas, wherein the oxygen plasma is generated through ionizing oxygen molecules by an exciting source. However, when the photoresist is removed through the ashing method, it is likely to damage the underlying material below the photoresist, and reaction between the oxygen plasma and the photoresist requires a relative high temperature, which increases cost. Additionally, as the ashing generally can not remove the photoresist completely, it is still necessary to clean in a detergent liquid for a long time, but it does not work well indeed, and there is still some residual photoresist.

The fully wet cleaning method is a method in which a detergent liquid formed by mixing hydrogen peroxide and sulfuric acid solution is sprayed on a surface of the photoresist of the semiconductor substrate so that the detergent liquid reacts with the photoresist to remove the photoresist, and then the surface of the semiconductor substrate is washed by deionized water after the photoresist is removed. With the fully wet cleaning method, it is possible to reduce the damage to the semiconductor material, however, concentration of the sulfuric acid is significantly decreased after the hydrogen peroxide is added, it takes a long time to wash. In addition, after reacting with the photoresist, the detergent liquid is directly discarded as waste liquid, the detergent liquid is needed to be replaced frequently, which reduces the life of the detergent liquid, and largely increases time and cost.

In the patterning processes, etching the film uncovered by the photoresist (or performing ion-doping) will enhance adhesion between the photoresist and the surface of the semiconductor substrate and increase hardness of the photoresist, and for current method for removing the photoresist, it is difficult to completely remove the firmly adhered photoresist (e.g. the photoresist after heavily doping ions are implanted or the photoresist after being dry etching for a long time), and the residual photoresist will degrade the performance of the final formed device or display apparatus.

### SUMMARY

Embodiments of the present disclosure provide a method for removing photoresist, which is capable of resolving the problem that the photoresist can not be removed completely at current.

At least one embodiment of the present disclosure provides a method for removing photoresist, which comprises:

depositing an oxide film on a substrate over which photoresist has been formed;

treating the oxide film by UV light;

peeling the oxide film off; and

removing the photoresist.

According to an embodiment of the present disclosure, the oxide film is a titanium oxide film.

According to an embodiment of the present disclosure, the titanium oxide film has a thickness of 10 nm to 50 nm.

According to an embodiment of the present disclosure, the UV light has a wavelength of 200 nm to 380 nm.

According to an embodiment of the present disclosure, the time period for treating the oxide film by the UV light is 200 seconds to 1000 seconds.

According to an embodiment of the present disclosure, before depositing an oxide film on the substrate over which photoresist has been formed, the method further comprises:

cleaning the substrate over which the photoresist has been formed.

According to an embodiment of the present disclosure, the depositing an oxide film on a substrate over which photoresist has been formed comprises depositing the oxide film on the substrate over which the photoresist has been formed through magnetron sputtering.

According to an embodiment of the present disclosure, the peeling the oxide film off comprises peeling the oxide film off by HF solution cleaning or wet etching.

According to an embodiment of the present disclosure, the removing the photoresist comprises removing the photoresist through wet etching.

According to an embodiment of the present disclosure, the substrate over which photoresist has been formed is a silicon substrate or a glass substrate over which photoresist has been formed.

At least one embodiment of the present disclosure provides a method for removing photoresist, in this method, by depositing an oxide film and treating the oxide film through the UV light, the photoresist is catalytically decomposed by the titanium oxide film to generate volatile gas such as carbon dioxide, or the like, and thus the photoresist can be removed completely.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic diagram illustrating a film pattern formed in the conventional patterning process;

FIG. 2 is a schematic diagram illustrating the method for removing photoresist according to an embodiments of the present disclosure;

FIG. 3 is a schematic view illustrating an oxide film deposited on the substrate according to an embodiment of the present disclosure; and

FIG. 4 is a schematic diagram illustrating another method for removing photoresist according to an embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

It should be noted that, the method for removing photoresist according to the embodiments of the present disclosure is used to remove the photoresist after a film is etched in the patterning processes. Wherein the patterning processes comprise coating photoresist on a film; exposing and developing the photoresist through a mask to form a photoresist removed portion and a photoresist remained portion after development; etching the film uncovered by the photoresist to form desired patterns; and removing the photoresist remained portion. The removing the photoresist after etching the film, i.e. as illustrated in FIG. 1, comprises subjecting photoresist 12 over a base substrate 10 to exposing and developing to form a photoresist removed portion (that is, area a in FIG. 1) and a photoresist remained portion; etching the film uncovered by the photoresist (i.e. the film on the area a as indicated in FIG. 1), to form desired patterns, and then removing the photoresist remained portion. The method provided by the embodiment of the present disclosure is mainly used to remove the photoresist remained portion on the film surface after the film patterns are formed.

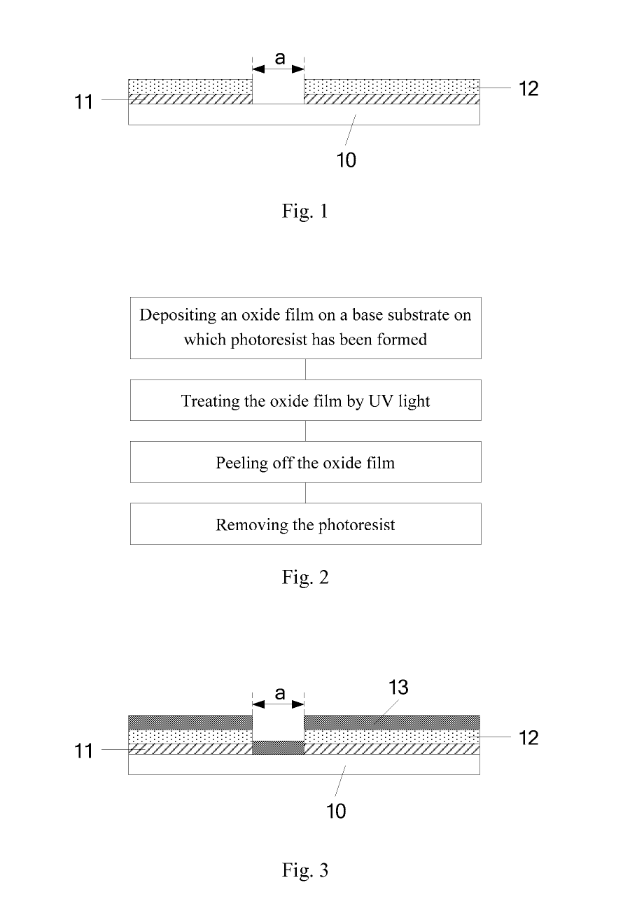

At least one embodiment of the present disclosure provides a method for removing photoresist, the method is mainly used to remove the photoresist remained portion after the film is etched in the patterning processes, as illustrated in FIG. 2, the method comprises:

depositing an oxide film on a substrate over which photoresist has been formed.

The depositing an oxide film on a substrate over which photoresist has been formed comprises depositing an oxide film by magnetron sputtering on the substrate over which the photoresist has been formed. As illustrated in FIG. 3, an titanium oxide film 13 is deposited on the base substrate 10, and at this time, as the photoresist removed portion and the photoresist remained portion have been formed after the photoresist 12 is subjected to exposing and developing, and after a portion of the film 11 uncovered by the photoresist is etched, the titanium oxide film is deposited, then the titanium oxide film not only covers the surface of the photoresist, but also covers the photoresist removed portion over the base substrate (i.e. the area a as indicated in FIG. 3). The embodiment of the present disclosure is described by taking the oxide film being a titanium oxide film as an example, and the deposited titanium oxide film has a thickness of 10 nm to 50 nm.

Of course, the oxide film can also be a film formed of other oxides, and the embodiment of the present disclosure and the attached drawings are described only by taking the oxide film being a titanium oxide film as an example. The oxide film can just cover the surface of the photoresist over the base substrate, and in the embodiment of the present disclosure, the oxide film is formed by magnetron sputtering, and then covers the photoresist and the photoresist removed area.

Next, the oxide film is treated by UV light.

The titanium film is irradiated by UV light. The adopted UV light can have a wavelength of 200 nm to 380 nm. The time period for treating oxide film by the UV light can be 200 seconds to 1000 seconds. Under the irradiation of the UV light, the titanium oxide film catalytically decomposes the photoresist to generate volatile gases such as carbon dioxide, or the like, and thus the photoresist is removed completely. Especially, after the film is etched or implanted with ions, adhesion between the photoresist and the surface of the semiconductor substrate is enhanced and hardness of the photoresist is increased so that the photoresist is difficult to be removed. However, by the method according to the embodiment of the present disclosure, after the photoresist releases carbon dioxide gas, the photoresist is easily removed without any residual, and the other film or device over the base substrate will not be damaged. Therefore, the performance of the device can be guaranteed, and the yield rate of the product is improved.

Then, peeling the oxide film off.

The peeling the oxide film off comprises peeling the oxide film off by HF solution cleaning or a wet etching. By HF solution cleaning or a wet etching, the oxide film is peeled off, and while the oxide film is peeled, the base substrate is cleaned, and the cleanness of the base substrate is improved.

After that, removing the photoresist.

The removing the photoresist comprises removing the photoresist by a wet etching. That is, while the photoresist is removed, the base substrate is cleaned, and the cleanness of the base substrate can be further improved.

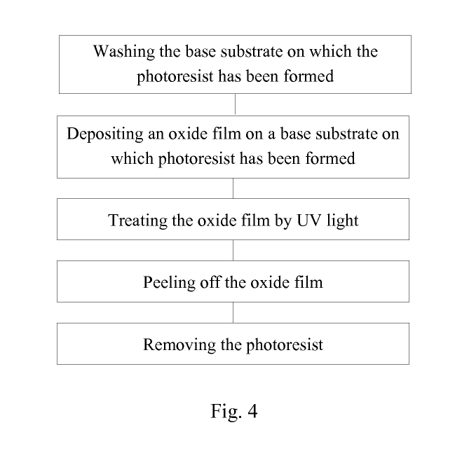

In one embodiment according to the present disclosure, as illustrated in FIG. 4, before depositing the oxide film over the base substrate over which the photoresist has been formed, the method further comprises cleaning the base substrate over which the photoresist has been formed.

The base substrate over which the photoresist has been formed can be a silicon substrate or a glass substrate over which the photoresist has been formed. Of course, other films or layer structures can also be formed over the base substrate, and in the embodiment of the present disclosure, how the photoresist is removed is described by taking the base substrate over which one film structure is formed as an example. Before the photoresist is removed, the base substrate is cleaned, by which other attachments on the photoresist can be cleaned away, so that the photoresist can be removed completely.

Embodiments of the present disclosure provide a method for removing photoresist. In this method, by depositing an oxide film and treating the oxide film by UV light, the photoresist is catalytically decomposed by the titanium oxide film to generate volatile gases such as carbon dioxide or the like, and thus the photoresist can be removed completely. Especially, after the film is etched or implanted with ions, adhesion between the photoresist and the surface of the semiconductor substrate is enhanced and hardness of the photoresist is increased so that the photoresist is difficult to be removed. However, by the method according to the embodiment of the present disclosure, after the photoresist releases carbon dioxide gas, the photoresist can be easily removed without any residual, and the method for removing photoresist provided by the present embodiment of the present disclosure will not damage other films or devices over the base substrate, the performance of the device can be guaranteed, and the yield rate of the product is improved.

The foregoing are merely exemplary embodiments of the disclosure, but are not used to limit the protection scope of the disclosure. The protection scope of the disclosure shall be defined by the attached claims.

The present application claims the priority of Chinese Patent Application No. 201410206695.9 filed on May 15, 2014, the disclosure of which is hereby entirely incorporated by reference.

1. A method for removing photoresist, comprising:
depositing an oxide film on a base substrate on which photoresist has been formed, wherein the oxide film is a titanium oxide film;
treating the oxide film by UV light;
peeling off the oxide film; and
removing the photoresist.

2. (canceled)

3. The method according to claim 1, wherein the oxide film has a thickness of 10 nm to 50 nm.

4. The method according to claim 1, wherein the UV light has a wavelength of 200 nm to 380 nm.

5. The method according to claim 1, wherein the time period for treating the oxide film is 200 s to 1000 s.

6. The method according to claim 1, wherein, before depositing the oxide film on the base substrate on which the photoresist has been formed, the method further comprises:
washing the base substrate on which the photoresist has been formed.

7. The method according to claim 1, wherein depositing an oxide film on a base substrate on which photoresist has been formed comprises depositing an oxide film on the base substrate on which the photoresist has been formed by magnetron sputtering.

8. The method according to claim 1, wherein peeling off the oxide film comprises peeling off the oxide film by HF solution washing or wet etching method.

9. The method according to claim 1, wherein removing the photoresist comprises removing the photoresist by wet etching method.

10. The method according to claim 1, wherein the base substrate on which the photoresist has been formed is a silicon substrate or a glass substrate on which the photoresist has been formed.

11-12. (canceled)

13. The method according to claim 3, wherein the UV light has a wavelength of 200 nm to 380 nm.

14. (canceled)

15. The method according to claim 3, wherein the time period for treating the oxide film is 200 s to 1000 s.

16. The method according to claim 4, wherein the time period for treating the oxide film is 200 s to 1000 s.

17. (canceled)

18. The method according to claim 3, wherein, before depositing the oxide film on the base substrate on which the photoresist has been formed, the method further comprises:
washing the base substrate on which the photoresist has been formed.

19. The method according to claim 4, wherein, before depositing the oxide film on the base substrate on which the photoresist has been formed, the method further comprises:
washing the base substrate on which the photoresist has been formed.

20. The method according to claim 5, wherein, before depositing the oxide film on the base substrate on which the photoresist has been formed, the method further comprises:
washing the base substrate on which the photoresist has been formed.
